(19) United States
(12) Patent Application Publication
(10) Pub. No.: US 2023/0033086 A1
(43) Pub. Date: Feb. 2, 2023

(54) VARYING CHANNEL WIDTH IN THREE-DIMENSIONAL MEMORY ARRAY

(71) Applicant: Intel Corporation, Santa Clara, CA (US)

(72) Inventors: Chen WANG, San Jose, CA (US); Dipanjan BASU, Portland, OR (US); Richard FASTOW, Cupertino, CA (US); Dimitri KIOUSSIS, San Jose, CA (US); Yi LI, Dalian, Liaoning (CN); Ebony Lynn MAYS, Morgan Hill, CA (US); Dimitrios PAVLOPOULOS, Glendale, CA (US); Junyen TEWG, Dalian, Liaoning (CN)

(21) Appl. No.: 17/791,175

(22) PCT Filed: Feb. 7, 2020
(86) PCT No.: PCT/CN20/74477

§ 371 Date: Jul. 6, 2022

(51) Int. Cl. H01L 27/11556; H01L 27/11582; H01L 27/11524; H01L 27/1157; G11C 8/14

(52) U.S. Cl. CPC H01L 27/11556; H01L 27/11582; H01L 27/11524; H01L 27/1157; G11C 8/14

(57) ABSTRACT

A memory array including a varying width channel is disclosed. The array includes a plurality of WLs, which are above a layer, where the layer can be, for example, a Select Gate Source (SGS) of the memory array, or an isolation layer to isolate a first deck of the array from a second deck of the array. The channel extends through the plurality of word lines and at least partially through the layer. In an example, the channel comprises a first region and a second region. The first region of the channel has a first width that is at least 1 nm different from a second width of the second region of the channel. In an example, the first region extends through the plurality of word lines, and the second region extends through at least a part of the layer underneath the plurality of word lines. In one case, the first width is at least 1 nm less than a second width of the second region of the channel.

### BACKGROUND

Three-dimensional (3D) memory has become increasingly popular in the last few years. Examples of 3D memory include 3D NAND memory, in which the memory cells are stacked vertically in multiple layers. 3D memory arrays achieve high density of memory cells at a lower cost per bit of storage, compared to, for example, two-dimensional (2D) memory arrays. 3D NAND memory arrays are being scaled up (vertically), by including multiple memory decks and/or a higher number of alternating layers (or tiers) per deck in the memory array. A tier includes a pair of the alternating layers (a word line layer and a dielectric layer), and is the basic building block of a memory cell in the memory array. However, there exists a number of non-trivial issues associated with such vertical scaling of 3D NAND memory arrays, as discussed herein in turn.

### BRIEF DESCRIPTION OF THE DRAWINGS

FIG. 1 illustrates a cross-sectional view of a memory array comprising a plurality of memory decks, where a channel associated with a memory deck of the memory array has varying width across a length of the channel, in accordance with some embodiments of this disclosure.

FIG. 2A illustrates a cross-sectional view of a memory array comprising a plurality of memory decks, where a channel associated with a memory deck of the memory array has varying width across a length of the channel, and wherein an interface between a wide region and a narrow region of the channel is laterally adjacent to a select gate source (SGS) of the memory array, in accordance with some embodiments of this disclosure.

FIG. 2B illustrates a cross-sectional view of a memory array comprising a single memory deck, where a channel associated with the memory deck has varying width across a length of the channel, and wherein an interface between a wide region and a narrow region of the channel is laterally adjacent to a select gate source (SGS) of the memory array, in accordance with some embodiments of this disclosure.

FIGS. 3A, 3B, 3C, 3C1, 3D, 3D1, 3D2, 3D3, 3E, 3F, 3G, 3H, 3I, 3J, 3K, and 3L collectively illustrate a method for forming a three-dimensional (3D) memory array, in which a channel has a varying thickness along a length of the channel, in accordance with some embodiments of this disclosure.

FIG. 4 illustrates an example computing system implemented with memory structures disclosed herein, in accordance with one or more embodiments of the present disclosure.

### DETAILED DESCRIPTION

A three-dimensional (3D) memory array structure is disclosed herein, which includes varying width of a channel along a length of a memory pillar. For example, the 3D memory array structure comprises two or more decks arranged in a vertical stack, each deck including alternating word lines (WL) and dielectric layers. For a lowermost deck of the memory array structure, the lowermost WL or dielectric layer of the corresponding WLs and the dielectric layers is on a select gate source (SGS). For a mid-level or a top-level deck, the lowermost WL or dielectric layer of the corresponding WLs and the dielectric layers is on a corresponding isolation region. Each deck comprises a corresponding memory pillar extending vertically through the WLs and the dielectric layers of the deck. Each pillar comprises a thin doped hollow channel (DHC) formed along a length of the pillar. In some embodiments, the channel has varying width along the length of the pillar. For example, a narrow region of the channel, having relatively smaller width, is adjacent to the WLs; and a wide region of the channel, having relatively larger width, is adjacent to the SGS (e.g., in case of the lowermost memory deck) or adjacent to an isolation region (e.g., in case of a mid-level or a top-level memory deck). In some such example embodiments and as will be discussed in further detail herein, varying the width of the channel in this manner facilitates vertical scaling (e.g., increasing the number of decks and/or a number of tiers per deck in a memory array), without compromising or sacrificing the erase performance and/or the cell electrostatics performance of the memory array. Numerous variations and embodiments will be apparent in light of this disclosure.

General Overview

As previously noted, there exists a number of non-trivial issues associated with vertical scaling of 3D NAND memory arrays. For example, a 3D NAND memory array comprises a relatively thin doped hollow channel (DHC) that has been formed along a memory pillar. Various components, such as a select gate source (SGS), non-volatile memory cells (NAND memory cells), control gates, and a select gate drain (SGD) are arranged along the channel. The channel is connected at one end to a bit line (BL) and at the other end to a current common source (SRC). In a multi-deck memory, channels of two adjacent decks are electrically interconnected through a corresponding inter-deck conductive plug. In multi-deck memory arrays having a higher number of tiers per deck, higher cell electrostatics is desirable, which can be achieved by relatively thinner channel near active word lines (WLs). In an example, higher cell electrostatics can lead to relatively better channel control, thus relatively better program and/or erase capability, relatively less data loss due to temperature change, and/or relatively less leakage current. On the other hand, higher erase speed is also desirable, which can be achieved by sufficient hole current density, which can in turn be achieved by relatively wider channel near the SGS and/or the inter-deck plugs. In this sense, there is a conflict in cases where both wider and thinner channels are desirable in different sections of the memory array. So, for instance, achieving a sharp junction with a relatively wide channel near the SGS to achieve higher current density during an erase operation is becoming increasingly challenging, as 3D NAND channel thickness has to be scaled down (relatively thin) to improve cell electrostatics. One possible solution to overcome this conflict is to rely on higher diffusion along the channel from the dopant source to the edge of the select gates to create reverse junction. For the lowest memory deck, this can be achieved by higher doping of the channel near the SGS region, whereas for middle or upper memory decks the higher doping can be near the inter-deck plugs. However, achieving high doping in this channel region has its own challenges. For example, for a relatively thin channel, thermally driven diffusion for the dopant movements may not be feasible, or fully achievable. In addition, diffusion uniformity trends to worsen at thinner channel thickness. As the tiers and/or number of decks increase in the 3D NAND architecture, there is a need for highly sufficient erase hole current from gate induced drain leakage (GIDL) with high uniformity to maintain erase performance, including speed and uniformity. Thus, without more, a trade between good electrostatics and erase speed has to be considered when using standard 3D NAND architecture.

Thus, and according to an embodiment of the present disclosure, a 3D NAND memory array is disclosed that comprises different channel width along a length of the channel. For example, such variation in channel width addresses the conflict involving a first desire for a thinner channel for cell electrostatics benefits and a second desire for wider channel requirements for GIDL generation. The relatively wider channel near the SGS and/or the interdeck plug region improves the GIDL current, by utilizing relatively large diffusion cross-section of wider polysilicon channel from a dopant source to the GIDL origination cell. The channel is thinner near active WL regions, thereby maintaining cell electrostatics benefits.

In some embodiments, a 3D NAND memory has multiple memory decks. For example, a first deck may be stacked on top of a second deck, which is stacked on top of a third deck, and so on. Each deck comprises alternating layers of word lines (WLs) and dielectric material. In some embodiments, the WLs comprise polysilicon and the dielectric layers comprise silicon dioxide, although other suitable conductive and dielectric materials can be used. Each period (or pair) of alternating layers provides a tier of the corresponding memory cell. For example, a memory cell is formed at a corresponding junction of a corresponding WL and a corresponding memory pillar. In some embodiments, the lowermost deck is formed on an SGS and a current common source SRC (also referred to as a source). An isolation region separates two adjacent decks. Mid-level or top-level decks are formed on corresponding isolation regions. Thus, for the multi-deck memory array, there is a single SGS and a single SRC underneath the lowest deck, according to some such example embodiments.

Each deck has a corresponding memory pillar, where the memory pillars of various decks are vertically aligned. Memory pillars of two adjacent decks are separated by a corresponding conductive inter-deck plug within a corresponding isolation region. In some embodiments, each memory pillar comprises a pillar core comprising non-conductive material, such as an appropriate oxide. Each memory pillar further includes a channel formed on the core. In some embodiments, the channel is a doped hollow channel (DHC) comprising appropriate semiconductor material. Non-limiting examples of material of the channel include silicon, polysilicon, gallium, gallium arsenide, and/or combinations thereof. In some embodiments, the semiconductor material of the channel is doped. In some embodiments, channels of two adjacent decks are electrically coupled via the corresponding inter-deck plug. As discussed, a memory cell is formed at or near a junction of a corresponding WL and a corresponding channel.

In some embodiments, the channel is formed to have width diversity along its length. For instance, in some embodiments, a channel is formed to include two regions: a narrow region and a wide region. In some embodiments, a width D1 of the wide region of a channel is substantially greater (e.g., at least 1 nanometer greater) than a width D2 of the narrow region of the channel. For example, a difference between the widths D1 and D2 is at least 2 nanometers (nm), or at least 3 nm, or at least 4 nm, or at least 5 nm. Merely as an example, the width D1 is 10 nm or more, such as in the range of 10 nm to 15 nm. On the other hand, the width D2 is in the range of 4 nm to 7 nm. In an example, the width D1 is at least 20%, 30%, or 50% greater than the width D2. The widths D1, D2 are horizontal widths, as illustrated.

In some embodiments, the width D1 may not be uniform along the wide region, and the width D2 may not be uniform along the narrow region. In one such embodiment, the width D1 is an average horizontal width of the wide region of the channel, and the width D2 is an average horizontal width of the narrow region of the channel. In another such embodiment, the width D1 is a minimum horizontal width of the wide region of the channel along a vertical length of the wide region; and the width D2 is a maximum horizontal width of the narrow region of the channel along a vertical length of the channel region.

In some embodiments, the width D1 is substantially uniform along the wide region, and the width D2 is substantially uniform along the narrow region. For instance, in one such embodiment, a minimum width of the wide region is less than 1 nm different than a maximum width of the wide region, and a minimum width of the narrow region is less than 1 nm different than a maximum width of the narrow region.

In a memory deck, the corresponding wide region of a channel is disposed underneath or below the narrow region, according to an embodiment. For example, for a lowermost deck of the memory array, the wide region is adjacent to the SGS, and the narrow region is adjacent to the WLs of the lowermost deck. A mid-level deck or a top-level deck of the memory array does not have any SGS, and for such a deck, the corresponding wide region is adjacent to the corresponding inter-deck plug, and the narrow region is adjacent to the corresponding WLs, according to an embodiment.

As discussed, the wide region of the channel adjacent to the SGS region or the inter-deck plug improves the GIDL current, by utilizing relatively large diffusion cross-section of wider polysilicon channel from a dopant source to the GIDL origination cell. On the other hand, the narrow region (i.e., a region having smaller channel width) of the channel is for active WL regions, which helps maintain cell electrostatics benefits. Thus, varying the width of the channel facilitates in scaling up a number of decks and/or a number of tiers per deck in a memory array, without compromising or sacrificing the erase performance and/or the cell electrostatics performance of the memory array.

In some embodiments, to form the varying channel width in the lowermost memory deck of a memory array, initially, a plurality of WLs and the SGS layer are formed. A trench is formed, the trench extending through the plurality of WLs and the SGS layers. In an example, the trench extends to a current common source SRC of the array. Semiconductor material of the channel is deposited on the sidewalls of the trench. The semiconductor material can be annealed, e.g., to create relatively large grain size in the semiconductor material. Such relatively large grain size, in some examples, results in a relatively low resistivity channel.

In some embodiments, upper portions of the trench, such as upper portions of the sidewalls of the semiconductor material, are exposed to plasma, which forms a plasma layer on the upper portions of the sidewalls of the semiconductor material of the channel. As will be discussed in further detail in turn, an exposure duration of the plasma can be controlled to fine-tune a region of the semiconductor material that is to be covered by the plasma. The plasma forms a passivation layer in the upper portions of the sidewalls of the semiconductor material (e.g., portions that are adjacent to the plurality of WLs). Lower portions of the sidewalls of the semiconductor channel material, which are adjacent to the SGS, are not covered by the plasma.

Subsequently, pillar core material is deposited within the trench to form a bottom section of a pillar core of the memory pillar. The plasma layer acts as a passivation layer, and prevents deposition of the pillar core material on the upper portions of the sidewalls of the semiconductor material that are covered by the plasma. Put differently, the pillar core material does not adhere to, and hence, is not deposited to upper portions of the sidewalls of the semiconductor material that are covered by the plasma. The pillar core material is deposited merely on the bottom section of the trench, which are not covered by the plasma. Thus, the pillar core material covers sections of the semiconductor material of the channel adjacent to the SGS, according to some embodiments.

The exposed semiconductor material (e.g., which is not covered or protected by the bottom portion of the pillar core) is then etched, to reduce its width. For example, wet etching is employed, where relatively hot APM (ammonium peroxide mixture) is used as an etchant. In an example, the etchant oxidizes the exposed polysilicon surface of the semiconductor material, thereby effectively decreasing the width of the semiconductor channel material.

This results in formation of a relatively wider channel region at the bottom of the trench, and a relatively narrower channel region at the upper portions of the trench. In some embodiments, the wider channel region is adjacent to, and extends through, the SGS region. In some such embodiments, the narrower channel region is adjacent to, and extends through, the WLs of the deck. Subsequently, rest of the trench is filed with the pillar core material, to fully form the memory pillar. This completes formation of the memory pillar for the lowermost deck of the memory array, according to some embodiments.

If the memory array includes multiple decks, one or more decks above the lowermost deck are also formed in a manner at least in part similar to the above discussion. For example, each deck also has a channel having varying widths, as discussed herein. Numerous variations and embodiments will be appreciated in light of this disclosure.

As discussed herein, terms referencing direction, such as upward, downward, vertical, horizontal, left, right, front, back, etc., are used for convenience to describe embodiments of integrated circuits having a base or substrate extending in a horizontal plane. Embodiments of the present disclosure are not limited by these directional references and it is contemplated that integrated circuits and device structures in accordance with the present disclosure can be used in any orientation.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer.

Note that, as used herein, the expression “X includes at least one of A or B” refers to an X that may include, for example, just A only, just B only, or both A and B. To this end, an X that includes at least one of A or B is not to be understood as an X that requires each of A and B, unless expressly so stated. For instance, the expression “X includes A and B” refers to an X that expressly includes both A and B. Moreover, this is true for any number of items greater than two, where “at least one of” those items are included in X. For example, as used herein, the expression “X includes at least one of A, B, or C” refers to an X that may include just A only, just B only, just C only, only A and B (and not C), only A and C (and not B), only B and C (and not A), or each of A, B, and C. This is true even if any of A, B, or C happens to include multiple types or variations. To this end, an X that includes at least one of A, B, or C is not to be understood as an X that requires each of A, B, and C, unless expressly so stated. For instance, the expression “X includes A, B, and C” refers to an X that expressly includes each of A, B, and C. Likewise, the expression “X included in at least one of A or B” refers to an X that may be included, for example, in just A only, in just B only, or in both A and B. The above discussion with respect to “X includes at least one of A or B” equally applies here, as will be appreciated.

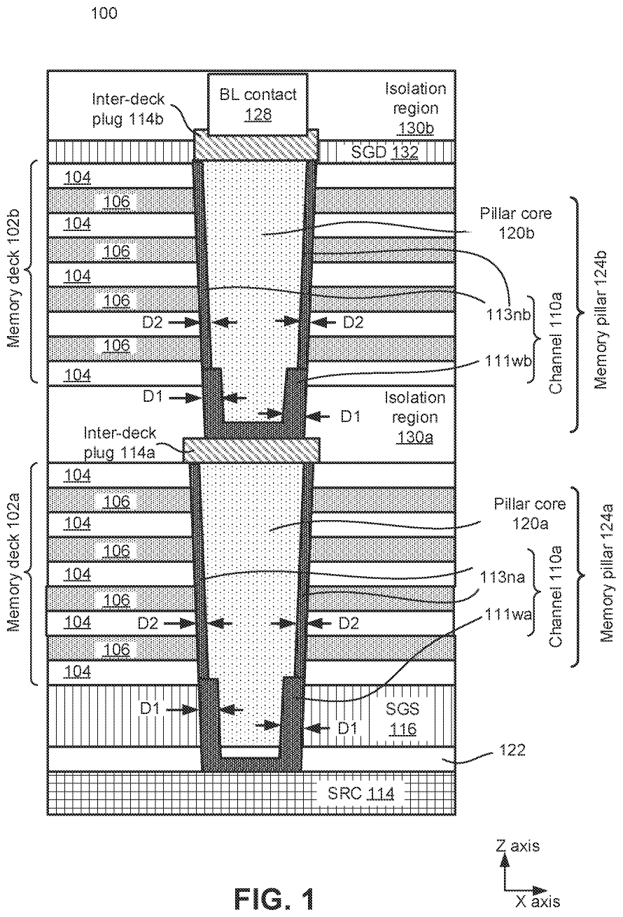

Elements referred to herein with a common reference label followed by a particular number or alphabet may be collectively referred to by the reference label alone. For example, a wide region 111wa of a channel 110a and a wide region 111wb of a channel 110b of FIG. 1 discussed herein later may be collectively and generally referred to as wide regions 111w in plural, and wide region 111w in singular. Similarly, the channels 110a, 110b may be collectively and generally referred to as channels 110 in plural, and channel 110 in singular.

Architecture and Methodology

FIG. 1 illustrates a cross-sectional view of a memory array (also referred to as an “array”) 100 comprising a plurality of memory decks 102a, 102b, where a channel 110 associated with a memory deck 102 of the memory array 100 has varying width across a length of the channel 110, in accordance with some embodiments of this disclosure.

In an example, the array 100 comprises any appropriate 3D memory array, such as a floating gate flash memory array, a charge-trap (e.g., replacement gate) flash memory array, a phase-change memory array, a resistive memory array, an ovonic memory array, a ferroelectric transistor random access memory (FeTRAM) array, a nanowire memory array, or any other 3D memory array. In one example, the memory array 100 is a stacked NAND flash memory array, which stacks multiple floating gates or charge-trap flash memory cells in a vertical stack wired in a NAND (not AND) fashion. In another example, the 3D memory array 100 includes NOR (not OR) storage cells. Although two memory decks 102a, 102b are illustrated for the array 100, in some examples, the array 100 can have any appropriate number of memory decks, such as three, four, or higher. For example, a first deck may be stacked on top of a second deck, which is stacked on top of a third deck, and so on.

Each deck 102 of array 100 comprises a tier formed of alternating layers of word lines (WLs) 106 and dielectric material 104. The dielectric material 104 comprises, for example, an oxide (e.g., silicon dioxide), a silicate glass, a low-k insulator (such as silicon oxycarbide), and/or other suitable dielectric material. The layers 104, 106 are disposed in a generally horizontal manner across the array 100. In an example, individual ones of the WLs form a corresponding WL of a corresponding memory cell. In some embodiments, the WLs 106 comprise polysilicon, although the WLs can include another appropriate material for word lines in a 3D memory array.

In some embodiments, the lowermost memory deck 102a is formed over a select gate source (SGS) 116 and a current common source SRC 114 (also referred to as a source). As seen in FIG. 1, the alternating layers 104, 106 of the lower deck 102a is above the SGS 116. In some embodiments, the SRC 114 comprises conductive material, such as semiconductor material, metal, and/or combinations and mixtures thereof. In one such embodiment, the SRC 114 comprises doped or heavily doped silicon, such as, for example, polysilicon. In another such embodiment, the SRC 114 comprises a silicide, including salicides and/or polycides. The SRC 114 forms source lines of the array 100.

In some embodiments, the SGS layer 116 is a MOSFET select gate coupling the SRC 114 to a plurality of charge storage devices formed within the various memory decks 102. In an example, the SGS 116 is electrically isolated from the SRC 114 by an insulating layer 122. The insulating layer 122 comprises any appropriate material that electrically insulates the SRC 114 and the SGS 116, such as an oxide, a nitride, a combination of oxide and nitride, and/or other appropriate electrically insulating material.

In some embodiments, the deck 102a comprises a memory pillar 124a (also referred to herein as pillar 124a), and the deck 102b comprises a memory pillar 124b. As illustrated, the pillars 124a, 124b are substantially aligned. For example, the pillar 124a is formed underneath the pillar 124b.

In some embodiments, the pillar 124a extends from the SRC 114, through the SGS 116 and the alternating tired layers 104, 106 of the deck 102a, and extends to an inter-deck plug 114a. In some embodiments, the pillar 124b extends from the inter-deck plug 114a, through the alternating tired layers 104, 106 of the deck 102b, and extends to another inter-deck plug 114b.

In some embodiments, a pillar 14 of a deck 102 is separated from another pillar of an adjacent deck by a corresponding inter-deck plug 114. For example, the pillar 124a of the deck 102a is separated from the pillar 124b of the deck 102b by a corresponding inter-deck plug 114a. Another inter-deck plug 114b is formed above the pillar 124b. Thus, if a third deck (not illustrated in FIG. 1) were to be above the deck 102b, then the inter-deck plug 114b would have separated the pillar 124b from a pillar of such a third deck. In the embodiment illustrated in FIG. 1, no such third deck is present, and a bitline (BL) contact is coupled to the inter-deck plug 114b.

In some embodiments, the inter-deck plug 114a protects the pillar 124a, when the pillar 124b and the deck 102b is formed above the pillar 124a, as will be discussed in further detail herein later. The inter-deck plugs 114 comprise an appropriate conductive material capable of protecting the underneath pillar, and establishing electrical connectivity between two memory pillars (or between a memory pillar and a BL contact). For example, the inter-deck plugs 114 comprise an appropriate semiconductor material, silicon, polysilicon, gallium, and/or gallium arsenide. In some embodiments, the inter-deck plugs 114 are un-doped, while in some other embodiments the inter-deck plugs 114 are doped or heavily doped. In an example, the inter-deck plugs 114 comprise a material that is the same as a material of channels 110 of the pillars 124, or that is different from the material of the channels 110.

In some embodiments, the decks 102a, 102b are separated by an isolation region 130a, and the deck 102b is separated from components above the deck 102b by another isolation region 130b. The isolation regions 130 comprise electrically insulating material, such as an oxide, a nitride, a combination of oxide and nitride, and/or other appropriate electrically insulating material.

Individual ones of the pillar 124 can be cylindrical or non-cylindrical. One example of a non-cylindrical pillar is a tapered pillar illustrated in FIG. 1. In some embodiments, the pillar 124a comprises corresponding pillar core 120a (also referred to as core 120a), and the pillar 124b comprises corresponding pillar core 120b. The core 120 of a pillar 124 forms an inside or central part of the corresponding pillar. In some embodiments, the cores 120 comprise non-conductive material, such as any appropriate oxide material, although any appropriate non-conductive material can be used.

In some embodiments, the pillar 124a comprises channels 110a formed on the core 120a, and the pillar 124b comprises channels 110b formed on the core 120b. In some embodiments, the channels 110 are doped hollow channel (DHC). The channels 110 comprise any appropriate conductor or semiconductor material, which can include a single or multiple different materials. Non-limiting examples of material of the channels 110 include silicon, polysilicon, gallium, gallium arsenide, and/or combinations thereof. In some embodiments, the semiconductor material of the channels 110 is doped. The channels 110 are also referred to herein as regions or layers comprising semiconductor material. In some embodiments, the channels 110 include conductive metal, metal mixture, metal alloy, and/or any appropriate conductive material.

In some embodiments, the channel 110a of the lower deck 102a is electrically coupled to the channel 110b of the upper deck 102b via the inter-deck plug 114a, and the channel 110b of the upper deck 102b is electrically coupled to the BL contact 128 via the inter-deck plug 114b.

In some embodiments, a memory cell is formed at or near a junction of a corresponding WL 104 and a corresponding channel 110. Thus, a plurality of memory cells is formed in the array 100, each cell at a corresponding junction of a WL 104 and a channel 110. Although not illustrated in FIG. 1 for purposes of illustrative clarity, various layers and components may be formed between a WL 104 and a corresponding channel 110. Such components and layers are used to form individual memory cells. Examples of such layers and components include one or more Inter-Poly Dielectric layers (IPD), a charge storage structure comprising a floating gate, and/or other layers or components used to form a memory cell at a junction of a WL and a channel. Thus, although not illustrated in FIG. 1 for purposes of illustrative clarity, the array 100 includes, at individual junctions of a memory pillar and a WL 106, one or more of: one or more oxide layers, IPD layers, floating gate layers, and/or any other layer or component that is typically present in such a memory array.

In some embodiments, a channel 110 has two regions: a narrow region 113n and a wide region 111w. For example, the channel 110a comprises a wide region 111wa and a narrow region 113na, and the channel 110b comprises a wide region 111wb and a narrow region 113nb.

In some embodiments, a width of the wide region 111w of the channel 110 is substantially greater than a width of the narrow region 113n of the channel. For example, as illustrated in FIG. 1, a width of the wide region 111w is D1, and a width of the narrow region 111n is D2. In some embodiments, the width D1 is substantially greater than the width D2. For example, a difference between the widths D1 and D2 is at least 3 nm, or at least 2 nm. Merely as an example, the width D1 is 10 nm or more, such as in the range of 10 nm to 15 nm. On the other hand, the width D2 is in the range of 4 nm to 7 nm. In an example, the width D1 is at least 20%, 30%, or 50% greater than the width D2.

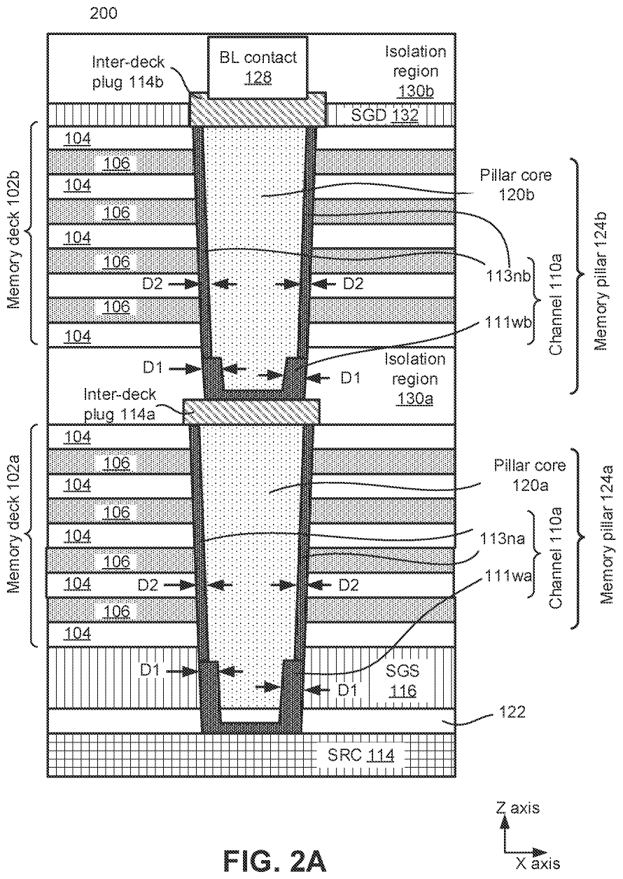

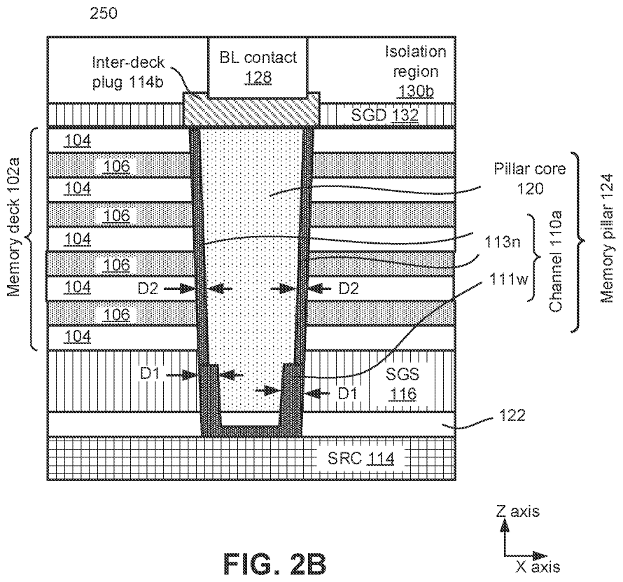

As illustrated in FIG. 1, in a memory deck 102, the wide region 111w of a channel 110 is disposed underneath the narrow region 113n. For example, for the lower deck 102a, the wide region 111wa is adjacent to the SGS 116. In the example of FIG. 1, the wide region 111wa is also adjacent to a lowest one of the dielectric layers 104. In contrast, FIG. 2A illustrates a cross-sectional view of a memory array (also referred to as an “array”) 200 comprising a plurality of memory decks 102a, 102b, where a channel 110 associated with a memory deck 102 of the memory array 100 has varying width across a length of the channel 110, and wherein an interface between a wide region 111wa and a narrow region 113na of the channel is adjacent to the select gate source (SGS) 116, in accordance with some embodiments of this disclosure. Thus, in the example of FIG. 2A, the wide region 111wa is adjacent to at least a part of the SGS 116, but not adjacent to the lowest one of the dielectric layers 104. In some embodiments and as illustrated in FIGS. 1 and 2A, the wide region 111wa may not be adjacent to any of the WLs 106 of the lower deck 102a.

As illustrated in FIG. 1, for the upper deck 102b, the wide region 111wb is adjacent to the isolation region 130a. In the example of FIG. 1, the wide region 111wb is also adjacent to a lowest one of the dielectric layers 104 in the deck 102b. In contrast, in the example of FIG. 2A, the wide region 111wb is adjacent to at least a part of the isolation region 130a, but not adjacent to the lowest one of the dielectric layers 104 of the deck 102b. In some embodiments and as illustrated in FIGS. 1 and 2A, the wide region 111wb may not be adjacent to any of the WLs 106 of the upper deck 102b.

FIGS. 1 and 2A illustrate a multi-deck 3D memory having varying channel width. However, such a varying channel width can be employed in a single-deck memory as well. FIG. 2B illustrates a cross-sectional view of a memory array 250 comprising a single memory deck 102, where a channel 110 associated with the memory deck 102 has varying width across a length of the channel 110, in accordance with some embodiments of this disclosure. The memory array 250 of FIG. 2B will be apparent from the memory arrays discussed with respect to FIGS. 1 and 2A, and hence, the memory array 250 will not be discussed in further detail herein.

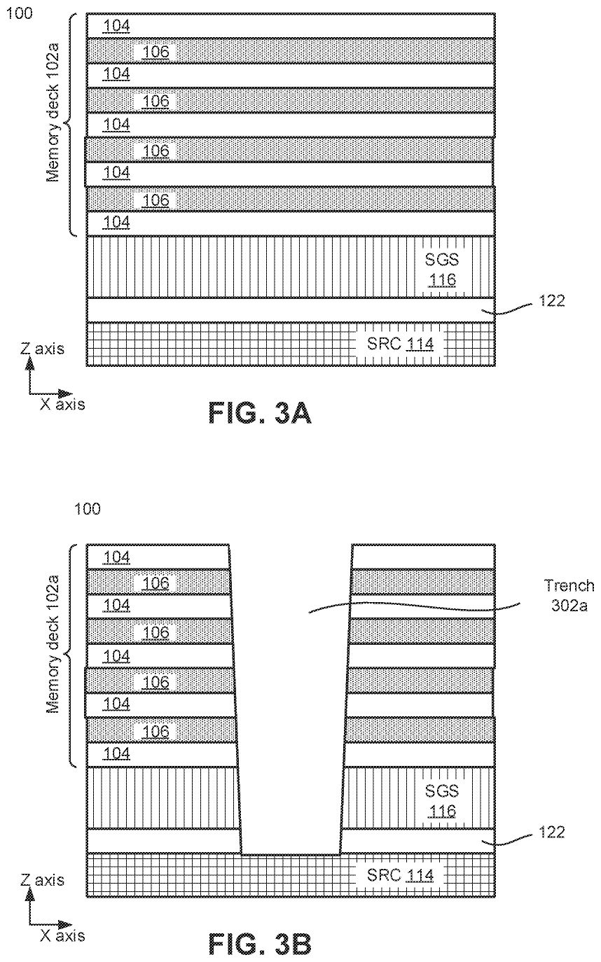

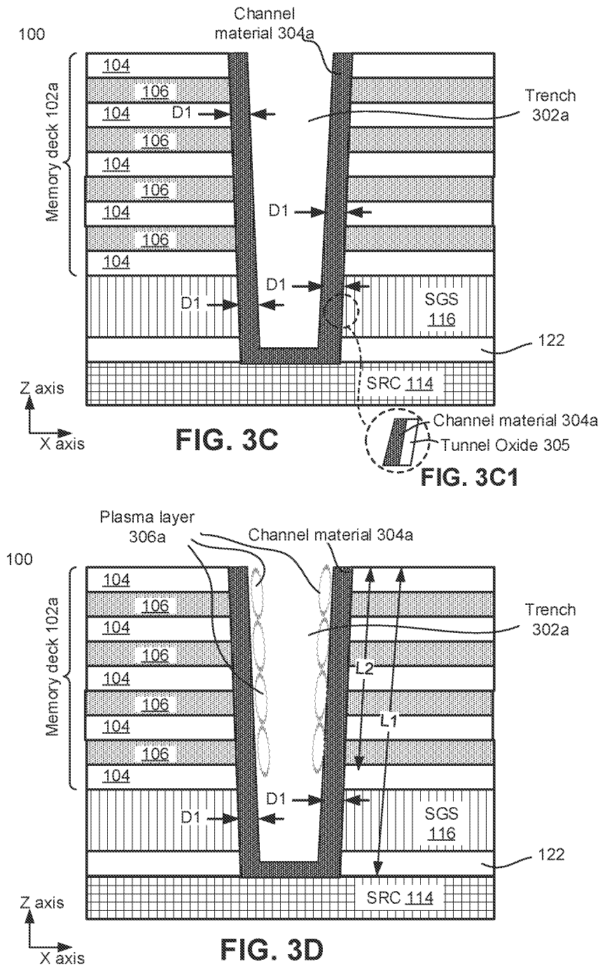

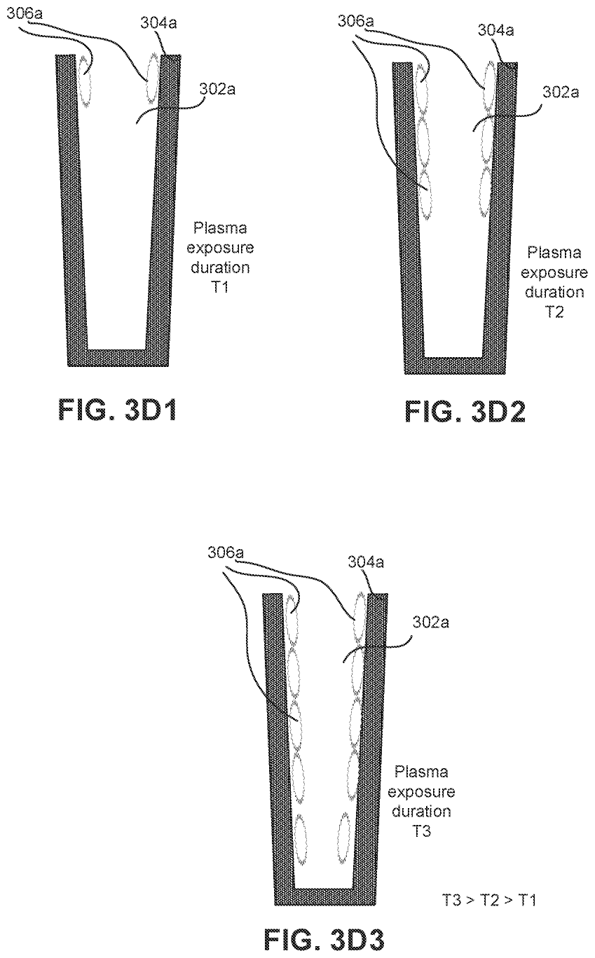

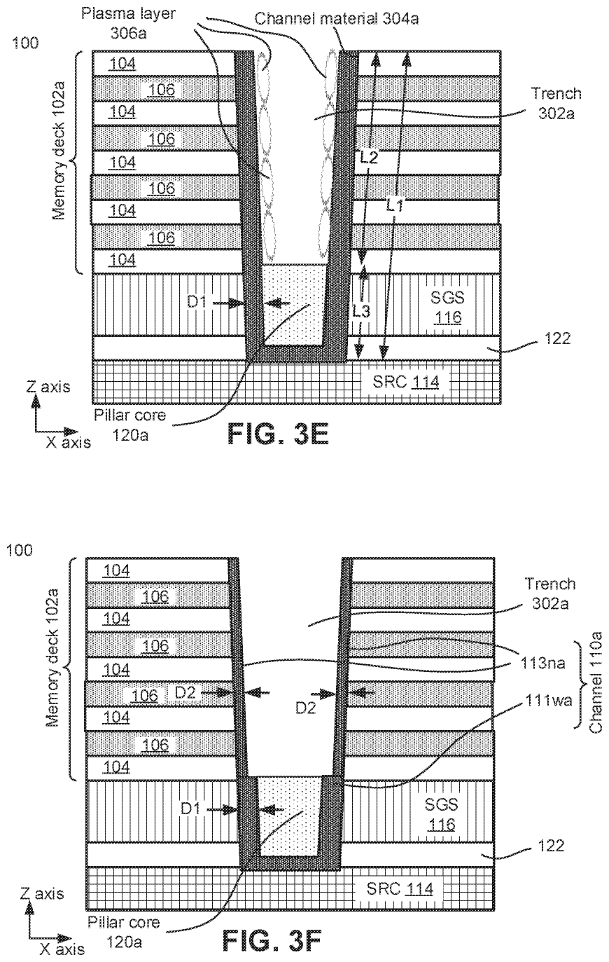

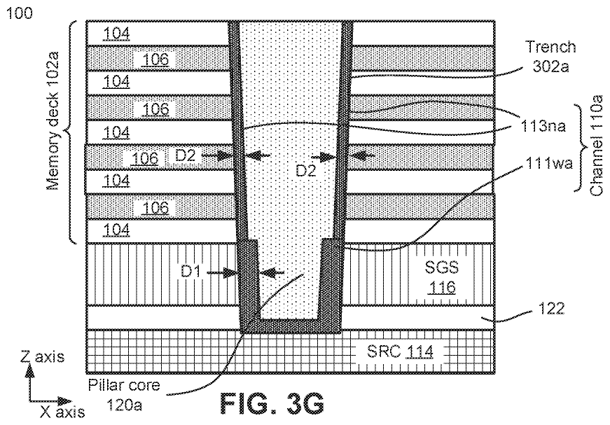

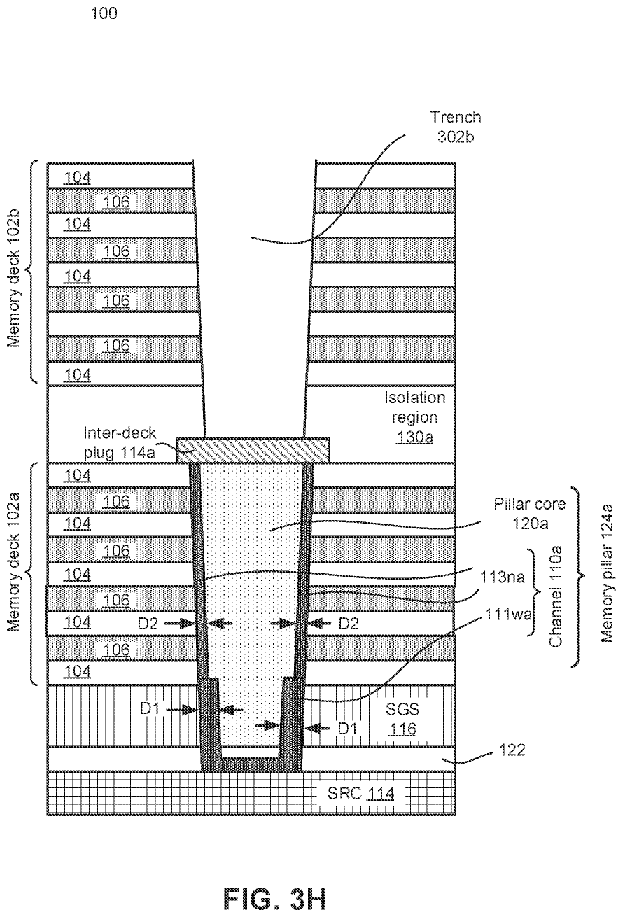

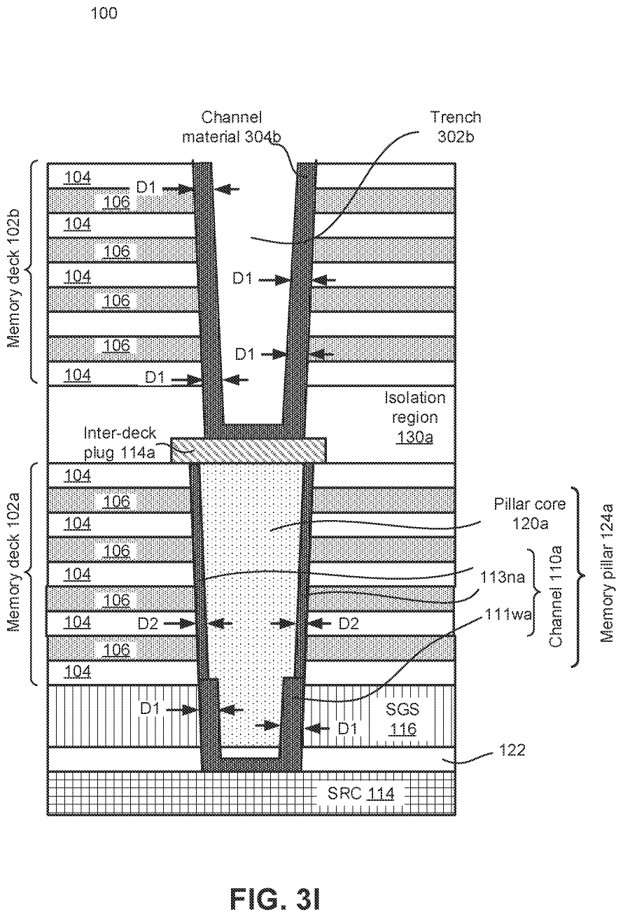

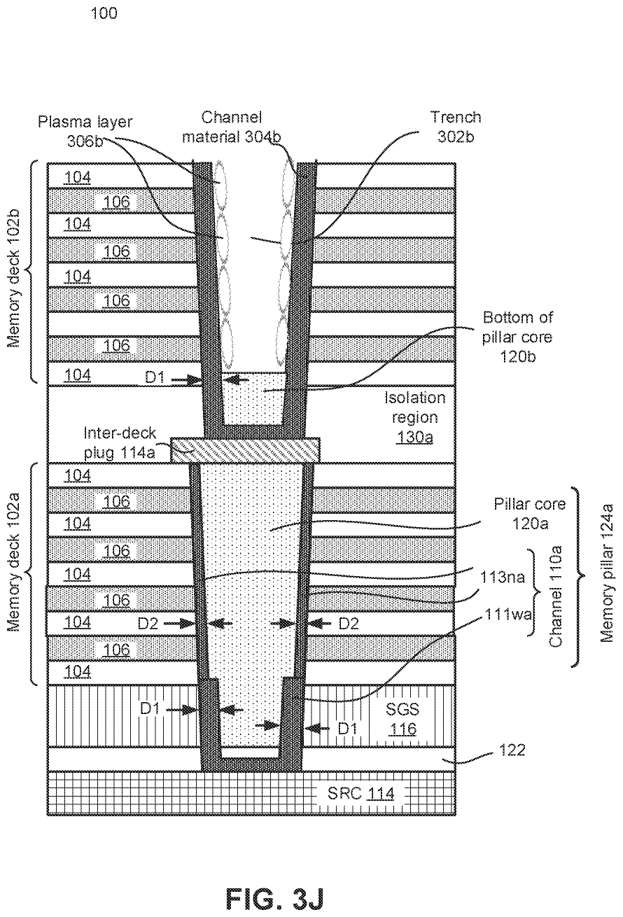

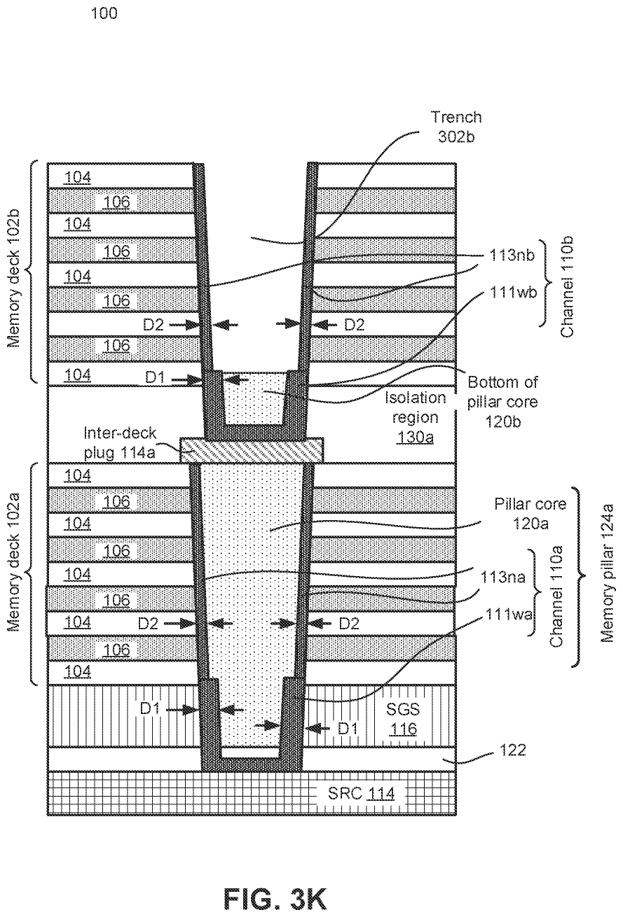

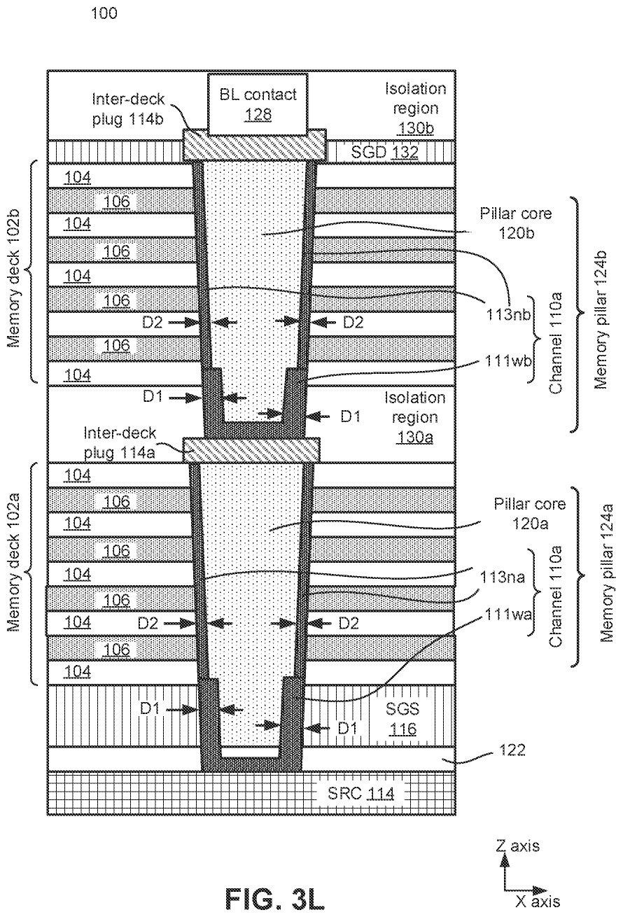

FIGS. 3A, 3B, 3C, 3D, 3D1, 3D2, 3E, 3F, 3G, 3H, 3I, 3J, 3K, and 3L collectively illustrate a method for forming a three-dimensional (3D) memory array, in which a channel has a varying thickness along a length of the channel, in accordance with some embodiments of this disclosure. These figures illustrate a cross-sectional view of the memory array 100 of FIG. 1, as the array 100 is formed.

Referring to FIG. 3A, illustrated are the alternating layers of WLs 106 and dielectric material 104 of the memory deck 102a, formed on the SGS 116, the insulating layer 122, and the SRC 114. The structure of FIG. 3A can be formed by deposition of material of the various layers.

Referring now to FIG. 3B, a trench 302a is formed through the alternating layers of WLs 106 and dielectric material 104, the SGS 116, and the SRC 114, such that the trench 302a reaches the SRC 114. The trench 302a can be formed using any appropriate directional or anisotropic etch process.

Referring now to FIG. 3C, channel material 304a is deposited on the sidewalls of the trench 302a. In some embodiments, the channel material 304a has a thickness D1, which corresponds to the thickness of the wide region 111wa of the channel 110a of FIG. 1. As further illustrated in FIG. 3C1, prior to the deposition of the channel material 304a, a layer of tunnel oxide 305 may be deposited on sidewalls of the trench 302a, and the channel material 304a may be deposited on the tunnel oxide material, according to some example embodiments of the present disclosure.

As discussed, the channel material 304a comprises any appropriate conductor or semiconductor material, which can include a single or multiple different materials. Non-limiting examples include silicon, polysilicon, gallium, gallium arsenide, and/or combinations thereof. In some embodiments, the channel material 304a comprises polysilicon. In some embodiments, subsequent to the deposition of the channel material 304a, the channel material 304a is annealed, e.g., to create relatively large grain size in the polysilicon channel material. Such relatively large grain size in the polysilicon channel, in some examples, results in a relatively low resistivity channel.

Referring now to FIG. 3D, upper portions of the trench 302a, such as upper portions of the sidewalls of the channel material 304a, are exposed to plasma, which forms a plasma layer 306a on sections of the sidewalls of the channel material 304a. The plasma layer 306a is symbolically illustrated using ovals having irregular sides. As illustrated, the plasma layer 306a is not deposited on the entirety of the sidewalls of the channel material 304a— rather, the plasma layer 306a is deposited on the upper portion of the sidewalls, e.g., corresponding to the sections of the narrow region of the channel. For example, as illustrated in FIG. 3D, the sidewalls of the channel material 304a has a length L1, and a length L2 from a top side of the sidewalls have the plasma deposited thereon, where L1 is greater than L2.

A portion of the sidewalls of the channel material 304a that is covered by the plasma layer 306a is based on a duration for which the structure 100 is exposed to plasma. Put differently, the length L2 can be controlled by controlling a duration of plasma exposure. For example, FIGS. 3D1, 3D2, 3D3 illustrate three examples, in which the structure 100 is exposed to plasma for time durations T1, T2, and T3, respectively, where T3 is greater than T2, and T2 is greater than T1. As seen, in FIG. 3D3, almost an entirety of the sidewalls is covered by the plasma layer 306a, as the channel material 304a is exposed to the plasma for a relatively longer time duration T3. In FIG. 3D2, about half of the sidewalls is covered by the plasma layer 306a. In FIG. 3D1, merely a top section of the sidewalls is covered by the plasma layer 306a, as the channel material 304a is exposed to the plasma for a relatively shorter time duration T1. Thus, the length L2 of FIG. 3D can be achieved by controlling a duration for which the structure 100 of FIG. 3D is exposed to the plasma.

Referring now to FIG. 3E, pillar core material is now deposited within the trench 302a, to form a bottom section of the pillar core 120a. The plasma layer 306a acts as a passivation layer, and prevents deposition of the pillar core material on the sections of the sidewalls of the channel material 304 that are covered by the plasma layer 306a. Put differently, the pillar core material does not adhere to, and hence, are not deposited to sections of the sidewalls of the channel material 304 that are covered by the plasma layer 306a. For example, sections of the sidewalls of the channel material 304, which are covered by the plasma layer 306a, are passivated and are non-selective to the pillar core material, and the pillar core material cannot adhere to the plasma covered section of the sidewalls of the channel material 304. Hence, the pillar core material is deposited merely on the bottom section of the trench, which are not covered by the plasma, as illustrated in FIG. 3E.

Any suitable deposition process may be used to form the bottom portion of the pillar core 102a, such as atomic layer deposition (ALD), plasma enhanced ALD (PEALD), physical vapor deposition (PVD), chemical vapor deposition (CVD), electrochemical deposition (ECD), molecular beam epitaxy (MBE), and/or other suitable deposition process. Thus, as discussed, the bottom portion of the pillar core 102a is formed by plasma surface treatment of top sections of the sidewalls of the channel material, and subsequent oxide growth via PEALD process is carried out in a bottom portion of the trench 302 not covered by the plasma, according to some example embodiments.

In an example, a height of the bottom portion of the pillar core 102a formed in FIG. 3E is L3, where L3 can be between 150 nm to 250 nm. As discussed with respect to FIGS. 1 and 2A, a top surface of the bottom portion of the pillar core 102a can be adjacent to either a section of the SGS 116, or a section of the bottom-most dielectric layer 104.

Referring now to FIG. 3F, the exposed channel material 304a (e.g., which are not covered or protected by the bottom portion of the pillar core 120a) is etched, to reduce its width from D1 to D2. For example, wet etching is employed, where relatively hot APM (ammonium peroxide mixture) is used as an etchant. In an example, the etchant oxidizes the exposed polysilicon surface of the channel material, thereby effectively decreasing the width of the polysilicon channel material. FIG. 3F illustrates the effective polysilicon channel having the width D2 (e.g., the width of the polysilicon), without illustrating the oxide formed due to the oxidation process. The bottom portion of the pillar core 120a protects the bottom section of the channel material 304 from being etched. In some other embodiments, any other appropriate type of etching technique can be employed to decrease the width of the exposed portion of the channel material 304a. It may be noted that the plasma does not prevent the etching process, and the plasma is also etched off or removed during the etch process.

Thus, the channel material 304a, on which the bottom portion of the pillar core 120a is deposited, forms the wide region 111wa of the channel 110a. As discussed with respect to FIG. 1, the wide region 111wa of the channel 110a has the width of D1. The partially etched portion of the channel material 304a, which now has the width of D2, forms the narrow region 113na of the channel 110a.

Referring to FIG. 3G, rest of the trench 302a is filed with the pillar core material, to fully form the pillar core 120a. In some embodiments, the pillar core material is filled by spin-on-dielectric (SOD), such as by spin-on-oxide material. This completes formation of the lower memory deck 102a.

Referring now to FIG. 3H, the inter-deck plug 114a, the isolation region 130a, and the alternating layers of WLs 106 and dielectric material 104 of the upper memory deck 102b are formed over the deck 102a, e.g., similar to the formation in FIG. 3A. A trench 302b is formed through the alternating layers of WLs 106 and dielectric material 104, such that the trench 302b reaches the inter-deck plug 114a, as discussed with respect to FIG. 3B.

Referring now to FIG. 3I, channel material 304b having thickness D1 is deposited on the sidewalls of the trench 302b, e.g., as discussed with respect to FIG. 3C.

Referring now to FIG. 3J, upper portions of the trench 3022 are exposed to plasma, which forms a plasma layer 306b on the sidewalls of the channel material 304b, as discussed in further detail with respect to FIG. 3D. Subsequently, a bottom portion of the pillar core 120b is deposited on the bottom of the trench 302b, as discussed in further detail with respect to FIG. 3E.

Referring now to FIG. 3K, the exposed channel material 304c (e.g., which are not covered or protected by the bottom portion of the pillar core 120b) is etched, to reduce its width from D1 to D2, as discussed in further detail with respect to FIG. 3F. Thus, the channel material 304b, on which the bottom portion of the pillar core 120b is deposited, forms the wide region 111wb of the channel 110b. The wide region 111wb of the channel 110b has the width of D1. The partially etched portion of the channel material 304b, which now has the width of D2, forms the narrow region 113nb of the channel 110b.

Referring to FIG. 3L, rest of the trench 302b is filed with the pillar core material, to fully form the pillar core 120b, as discussed with respect to FIG. 3G. Subsequently, the SGD 132, the inter-deck plug 114b, the isolation region 130b, and the BL contact 128 are formed, thereby forming the memory array 100 of FIG. 1.

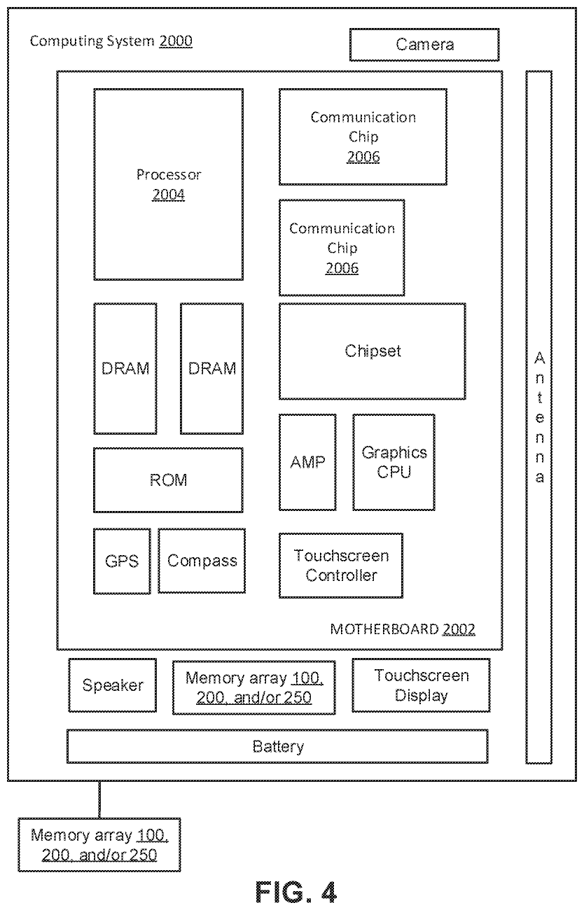

FIG. 4 illustrates an example computing system implemented with memory structures disclosed herein, in accordance with one or more embodiments of the present disclosure. As can be seen, the computing system 2000 houses a motherboard 2002. The motherboard 2002 may include a number of components, including, but not limited to, a processor 2004 and at least one communication chip 2006, each of which can be physically and electrically coupled to the motherboard 2002, or otherwise integrated therein. As will be appreciated, the motherboard 2002 may be, for example, any printed circuit board, whether a main board, a daughterboard mounted on a main board, or the only board of system 2000, etc.

Depending on its applications, computing system 2000 may include one or more other components that may or may not be physically and electrically coupled to the motherboard 2002. These other components may include, but are not limited to, volatile memory (e.g., DRAM), non-volatile memory (e.g., ROM, flash memory such as 3D NAND flash memory), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). In some embodiments, multiple functions can be integrated into one or more chips (e.g., for instance, note that the communication chip 2006 can be part of or otherwise integrated into the processor 2004).

In some embodiments, the computing system 2000 may include one or more of the memory array 100, 200, and/or 250 discussed herein. In some embodiments, the computing system 2000 may be coupled to one or more of the memory array 100, 200, and/or 250 discussed herein, where such memory array may be external to the computing system 2000. As discussed, the memory array discussed herein and included in the computing system 2000 and/or coupled to the computing system 2000 may have channels with varying thickness, as discussed herein.

The communication chip 2006 enables wireless communications for the transfer of data to and from the computing system 2000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 2006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 2000 may include a plurality of communication chips 2006. For instance, a first communication chip 2006 may be dedicated to shorter range wireless communications such as Wi-Fi and Bluetooth and a second communication chip 2006 may be dedicated to longer range wireless communications such as GPS, EDGE, GPRS, CDMA, WiMAX, LTE, Ev-DO, and others.

The processor 2004 of the computing system 2000 includes an integrated circuit die packaged within the processor 2004. The term “processor” may refer to any device or portion of a device that processes, for instance, electronic data from registers and/or memory to transform that electronic data into other electronic data that may be stored in registers and/or memory.

The communication chip 2006 also may include an integrated circuit die packaged within the communication chip 2006. As will be appreciated in light of this disclosure, note that multi-standard wireless capability may be integrated directly into the processor 2004 (e.g., where functionality of any chips 2006 is integrated into processor 2004, rather than having separate communication chips). Further note that processor 2004 may be a chip set having such wireless capability. In short, any number of processor 2004 and/or communication chips 2006 can be used. Likewise, any one chip or chip set can have multiple functions integrated therein.

In various implementations, the computing system 2000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices, as variously described herein.

### FURTHER EXAMPLE EMBODIMENTS

Numerous variations and configurations will be apparent in light of this disclosure and the following examples.

Example 1. A memory array comprising: a plurality of word lines arranged in a vertical stack; and a channel extending vertically through the plurality of word lines, wherein the channel comprises a first region and a second region below the first region, the first region of the channel having a first width that is at least 1 nm less than a second width of the second region of the channel.

Example 2. The memory array of example 1, further comprising: a layer underneath the plurality of word lines, wherein the channel extends through at least a part of the layer, wherein the first region of the channel extends through the plurality of word lines, and wherein the second region of the channel extends through at least a part of the layer underneath the plurality of word lines.

Example 3. The memory array of example 2, wherein the layer is one of (i) a Select Gate Source (SGS) of the memory array, or (ii) an isolation layer to isolate a first memory deck of the memory array from a second memory deck of the memory array.

Example 4. The memory array of any of examples 2-3, wherein the first width of the first region is at least 3 nm less than the second width of the second region.

Example 5. The memory array of any of examples 1-4, wherein: the plurality of word lines is a first plurality of word lines, and the channel is a first channel; the first plurality of word lines and the first channel are included in a first memory deck of the memory array; the memory array further comprises a second memory deck comprising a second plurality of word lines and a second channel; the first memory deck and the second memory deck are separated by an inter-deck plug and an isolation region; and the second channel comprises a third region and a fourth region, the third region of the second channel having a third width that is different from a fourth width of the fourth region of the second channel, the third width being at least 1 nm different from the fourth width.

Example 6. The memory array of example 5, wherein: the first memory deck is underneath the second memory deck; the first plurality of word lines of the first memory deck are above a select gate source (SGS), and the second plurality of word lines of the second memory deck are above the isolation region; the first region of the first channel is laterally adjacent to the word lines of the first plurality of word lines; the second region of the channel is laterally adjacent to the SGS, the second width being greater than the first width; the third region of the second channel is laterally adjacent to the word lines of the second plurality of word lines; and the fourth region of the second channel is laterally adjacent to the isolation region and the inter-deck plug, the fourth width being greater than the third width.

Example 7. The memory array of any of examples 1-6, wherein the first width is different from the second width by at least 5 nanometers.

Example 8. The memory array of any of examples 1-7, wherein the first width is at least 10 nanometers, and the second width is in a range of 4-7 nanometers.

Example 9. The memory array of any of examples 1-8, further comprising: a plurality of memory cells, each memory cell formed at a corresponding junction of a corresponding WL and the channel.

Example 10. The memory array of any of examples 1-9, wherein the channel is a Doped Hollow Channel (DHC).

Example 10A. The memory array of any of examples 1-4, wherein: the first width is an average horizontal width of the first region of the channel; and the second width is an average horizontal width of the second region of the channel.

Example 10B. The memory array of any of examples 1-4, wherein: the first width is a maximum horizontal width of the first region of the channel along a vertical length of the first region; and the second width is a minimum horizontal width of the second region of the channel along a vertical length of the second region.

Example 10C. The memory array of any of examples 1-4, wherein the first and second widths are uniform along the first and second regions, respectively, such that a minimum width of the first region is less than 1 nm different than a maximum width of the first region, and a minimum width of the second region is less than 1 nm different than a maximum width of the second region.

Example 11. The memory array of any of examples 1-10, wherein the memory array is flash memory array.

Example 12. The memory array of any of examples 1-11, wherein the memory array is three-dimensional (3D) NAND flash memory array.

Example 13. A printed circuit board, wherein the memory array of any of examples 1-12 is attached to the printed circuit board.

Example 14. A computing system comprising the memory array of any of examples 1-14.

Example 15. An integrated circuit memory comprising: a select gate source (SGS) layer; a memory pillar comprising (i) a pillar core, and (ii) a region comprising semiconductor material on the pillar core, wherein the memory pillar extends vertically through the SGS layer, and wherein the region comprising semiconductor material has a first section with a first width, and a second section with a second width that is different from the first width, the first width being at least 1 nm different from the second width.

Example 16. The integrated circuit memory of example 15, further comprising: a current common source underneath the SGS layer, wherein the memory pillar extends from the SGS layer.

Example 17. The integrated circuit memory of any of examples 15-16, further comprising: first, second, third, and fourth layers arranged in a vertical stack and above the SGS layer, wherein the first and third layers comprise an insulator material, and the second and fourth layers comprise a conductive material, wherein the memory pillar extends through the first, second, third, and fourth layers, and wherein the first section of the region extends through the SGS layer, and the second section of the region extends through the second and fourth layers.

Example 18. The integrated circuit memory of example 17, wherein the region is a first region, the memory pillar is a first memory pillar, the pillar core is a first pillar core, and wherein the integrated circuit memory further comprises: an isolation region above the fourth layer; fifth, sixth, seventh, and eight layers stacked above the isolation region, wherein the fifth and seventh layers comprise an insulator material, and the sixth and eight layers comprise a conductive material; and a second memory pillar comprising (i) a second pillar core, and (ii) a second region comprising semiconductor material on the second pillar core, wherein the second region comprising semiconductor material has (i) a first section with the first width that extends through the isolation region, and (iii) a second section with the second width that extends through the sixth and eight layers.

Example 19. The integrated circuit memory of example 18, further comprising: an inter-deck plug comprising electrically conductive material, the inter-deck plug disposed between the first and second memory pillars.

Example 20. The integrated circuit memory of any of examples 17-19, further comprising: a first memory cell formed at a junction between the second layer and the region comprising semiconductor material; and a second memory cell formed at a junction between the fourth layer and the region comprising semiconductor material.

Example 21. The integrated circuit memory of example 20, wherein the second layer and the fourth layer respectively form a first WL and a second WL for the first and second memory cells, respectively.

Example 22. The integrated circuit memory of any of examples 15-21, wherein the first width is different from the second width by at least 3 nanometers.

Example 23. The integrated circuit memory of any of examples 15-22, wherein the region comprising semiconductor material is a doped hollow channel (DHC).

Example 24. The integrated circuit memory of any of examples 15-23, wherein the integrated circuit memory is a three-dimensional (3D) flash memory array.

Example 25. A printed circuit board, wherein the integrated circuit memory of any of examples 15-24 is attached to the printed circuit board.

Example 26. A computing system comprising the integrated circuit memory of any of examples 15-25.

Example 27. A method to form a memory array, the method comprising: forming a select gate source (SGS), and a first word line (WL) and a second WL above the SGS; forming a trench that extends through the SGS and the first and second WLs; depositing semiconductor material on sidewalls of the trench; depositing material comprising oxide to partially fill the trench, such that a first region of the semiconductor material is covered by the material comprising oxide, and a second region of the semiconductor material is not covered by the material comprising oxide; and etching the second region of the semiconductor material, wherein the material comprising oxide prevents the first region of the semiconductor material from being etched, wherein subsequent to etching the second region of the semiconductor material, the second region has a second width that is less than a first width of the first region.

Example 28. The method of example 27, further comprising: subsequent to etching the second region of the semiconductor material, further depositing material comprising oxide to substantially completely fill the trench.

Example 29. The method of any of examples 27-28, wherein depositing the material comprising oxide to partially fill the trench comprises: exposing the trench to plasma, wherein the plasma forms a passivation layer on the second region, without forming the passivation layer on the first region; and subsequent to exposing the trench to plasma, depositing the material comprising oxide in the trench, wherein the passivation layer on the second region prevents the material comprising oxide to be deposited on the second region, and wherein the material comprising oxide is deposited on the first region.

Example 30. The method of any of examples 27-29, wherein depositing the material comprising oxide in the trench comprises: depositing the material comprising oxide in the trench using plasma enhanced atomic layer deposition (PEALD).

Example 31. The method of any of examples 27-30, further comprising: subsequent to depositing the semiconductor material on sidewalls of the trench, annealing the semiconductor material.

The foregoing detailed description has been presented for illustration. It is not intended to be exhaustive or to limit the disclosure to the precise form described. Many modifications and variations are possible in light of this disclosure. Therefore it is intended that the scope of this application be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

1.-25. (canceled)

26. A memory array comprising:
a plurality of word lines arranged in a vertical stack; and
a channel extending vertically through the plurality of word lines, wherein the channel comprises a first region and a second region below the first region, the first region of the channel having a first width that is at least 1 nm less than a second width of the second region of the channel.

27. The memory array of claim 26, further comprising:
a layer underneath the plurality of word lines, wherein the channel extends through at least a part of the layer,
wherein the first region of the channel extends through the plurality of word lines, and
wherein the second region of the channel extends through at least a part of the layer underneath the plurality of word lines.

28. The memory array of claim 27, wherein the layer is one of (i) a Select Gate Source (SGS) of the memory array, or (ii) an isolation layer to isolate a first memory deck of the memory array from a second memory deck of the memory array.

29. The memory array of claim 27, wherein the first width of the first region is at least 3 nm less than the second width of the second region.

30. The memory array of claim 29, wherein:
the plurality of word lines is a first plurality of word lines, and the channel is a first channel;
the first plurality of word lines and the first channel are included in a first memory deck of the memory array;
the memory array further comprises a second memory deck comprising a second plurality of word lines and a second channel;
the first memory deck and the second memory deck are separated by an inter-deck plug and an isolation region; and
the second channel comprises a third region and a fourth region, the third region of the second channel having a third width that is different from a fourth width of the fourth region of the second channel, the third width being at least 1 nm different from the fourth width.

31. The memory array of claim 30, wherein:
the first memory deck is underneath the second memory deck;
the first plurality of word lines of the first memory deck are above a select gate source (SGS), and the second plurality of word lines of the second memory deck are above the isolation region;
the first region of the first channel is laterally adjacent to the word lines of the first plurality of word lines;
the second region of the channel is laterally adjacent to the SGS, the second width being greater than the first width;
the third region of the second channel is laterally adjacent to the word lines of the second plurality of word lines; and
the fourth region of the second channel is laterally adjacent to the isolation region and the inter-deck plug, the fourth width being greater than the third width.

32. The memory array of claim 29, wherein the first width is different from the second width by at least 5 nanometers.

33. The memory array of claim 29, wherein the first width is at least 10 nanometers, and the second width is in a range of 4-7 nanometers.

34. The memory array of claim 29, further comprising:
a plurality of memory cells, each memory cell formed at a corresponding junction of a corresponding WL and the channel.

35. The memory array of claim 29, wherein the channel is a Doped Hollow Channel (DHC).

36. The memory array of claim 29, wherein:
the first width is an average horizontal width of the first region of the channel; and
the second width is an average horizontal width of the second region of the channel.

37. The memory array of claim 29, wherein:
the first width is a maximum horizontal width of the first region of the channel along a vertical length of the first region; and
the second width is a minimum horizontal width of the second region of the channel along a vertical length of the second region.

38. The memory array of claim 29, wherein the first and second widths are uniform along the first and second regions, respectively, such that a minimum width of the first region is less than 1 nm different than a maximum width of the first region, and a minimum width of the second region is less than 1 nm different than a maximum width of the second region.

39. The memory array of claim 29, wherein the memory array is three-dimensional (3D) NAND flash memory array.

40. The memory array of claim 26, wherein the memory array is attached to a printed circuit board.

41. The memory array of claim 26, wherein the memory array is included in a computing system.

42. An integrated circuit memory comprising:
a select gate source (SGS) layer; and
a memory pillar comprising (i) a pillar core, and (ii) a region comprising semiconductor material on the pillar core, wherein the memory pillar extends vertically through the SGS layer, and wherein the region comprising semiconductor material has a first section with a first width, and a second section with a second width that is different from the first width, the first width being at least 1 nm different from the second width.

43. The integrated circuit memory of claim 42, further comprising:
a current common source underneath the SGS layer,
wherein the memory pillar extends from the current common source.

44. The integrated circuit memory of claim 42, further comprising:
first, second, third, and fourth layers arranged in a vertical stack and above the SGS layer, wherein the first and third layers comprise an insulator material, and the second and fourth layers comprise a conductive material,
wherein the memory pillar extends through the first, second, third, and fourth layers, and
wherein the first section of the region extends through the SGS layer, and the second section of the region extends through the second and fourth layers.

45. The integrated circuit memory of claim 44, wherein the region is a first region, the memory pillar is a first memory pillar, the pillar core is a first pillar core, and wherein the integrated circuit memory further comprises:
an isolation region above the fourth layer;
fifth, sixth, seventh, and eight layers stacked above the isolation region, wherein the fifth and seventh layers comprise an insulator material, and the sixth and eight layers comprise a conductive material; and
a second memory pillar comprising (i) a second pillar core, and (ii) a second region comprising semiconductor material on the second pillar core,
wherein the second region comprising semiconductor material has (i) a first section with the first width that extends through the isolation region, and (iii) a second section with the second width that extends through the sixth and eight layers.

46. The integrated circuit memory of claim 44, further comprising:
a first memory cell formed at a junction between the second layer and the region comprising semiconductor material; and
a second memory cell formed at a junction between the fourth layer and the region comprising semiconductor material.

47. The integrated circuit memory of claim 45, wherein the second layer and the fourth layer respectively form a first WL and a second WL for the first and second memory cells, respectively.

48. A method to form a memory array, the method comprising:
forming a select gate source (SGS), and a first word line (WL) and a second WL above the SGS;
forming a trench that extends through the SGS and the first and second WLs;
depositing tunnel oxide on sidewalls of the trench;
depositing semiconductor material on tunnel oxide;
depositing material comprising oxide to partially fill the trench, such that a first region of the semiconductor material is covered by the material comprising oxide, and a second region of the semiconductor material is not covered by the material comprising oxide; and
etching the second region of the semiconductor material, wherein the material comprising oxide prevents the first region of the semiconductor material from being etched,
wherein subsequent to etching the second region of the semiconductor material, the second region has a second width that is less than a first width of the first region.

49. The method of claim 48, further comprising:
subsequent to etching the second region of the semiconductor material, further depositing material comprising oxide to substantially completely fill the trench

50. The method of any of claim 49, wherein depositing the material comprising oxide to partially fill the trench comprises:
exposing the trench to plasma, wherein the plasma forms a passivation layer on the second region, without forming the passivation layer on the first region; and
subsequent to exposing the trench to plasma, depositing the material comprising oxide in the trench, wherein the passivation layer on the second region prevents the material comprising oxide to be deposited on the second region, and wherein the material comprising oxide is deposited on the first region.
